(19) United States
(12) Patent Application Publication
(10) Pub. No.: US 2023/0191406 A1
(43) Pub. Date: Jun. 22, 2023

(54) HEATING DEVICE AND MICROFLUIDIC APPARATUS COMPRISING THE SAME

(71) Applicant: CYTESI, INC., Menlo Park, CA (US)

(72) Inventors: Tung-Yu WU, Hsinchu City (TW); Tang-Hung PO, Zhubei City (TW); CHUNG-YI WANG, Zhubei City (TW)

(21) Appl. No.: 18/074,142

(22) Filed: Dec. 2, 2022

Related U.S. Application Data
(60) Provisional application No. 63/290,160, filed on Dec. 16, 2021.

(51) Int. Cl. B01L 3/00; B81B 7/00; B01L 7/00

(52) U.S. Cl. CPC B01L 3/50273; B01L 7/54; B81B 7/0096; B01L 2300/0645; B01L 2300/1827; B01L 2400/0427; B81B 2201/057

(57) ABSTRACT

There is provided a heating device to independently and/or effectively heat the micro objects manipulated by a micro apparatus/system, for example the droplets of fluids in an electrowetting on dielectric EWOD device of a microfluidic apparatus. The heating device may include a plurality of micro heaters arranged in an array of rows and columns, and the micro heaters of the heating device may be disposed in relative to the electrode elements of the EWOD device, respectively. Therefore, the micro heaters of the heating device may heat one of the electrode elements of the EWOD device, thereby preventing thermal effect of the micro object on the other electrode elements.

### CROSS-REFERENCE TO RELATED APPLICATIONS

This application claims the benefit and priority to the U.S. Provisional Pat. Application No. 63/290,160 filed on Dec. 16, 2021, the entirety of which is incorporated herein by reference.

### TECHNICAL FIELD

The present disclosure generally relates to a heating device. More particularly, the present disclosure relates to a heating device comprising micro heaters arranged in an array of rows and columns. The present disclosure also relates to a microfluidic apparatus comprising such heating device.

### BACKGROUND

The microfluidic apparatus includes electrodes to manipulate or process droplets of fluid (e.g., moving, splitting, merging or heating the droplets) in a defined space of the panel/substrate in the microfluidic apparatus. The microfluidic apparatus may utilize an electrowetting on dielectric (EWOD) technique. That is, when a droplet of fluid is present on or above one of the electrodes of the apparatus and an electrical potential is applied to that electrode, the contact angle on the interface between the droplet and the electrode is changed, thereby generating a lateral pushing force to cause the droplet to move on the electrode.

In certain applications of the microfluidic apparatus, the droplets of fluid need to be manipulated under a preset temperature by a heater attached to or included in the microfluidic apparatus. The heater may generate heat to cause the temperature within microfluidic apparatus to generally raise, but this heater cannot make the droplets in different areas (i.e., electrodes in the pixels) of the microfluidic apparatus have different temperatures. Namely, such conventional heater may not be suitable for independent heating of the pixels of the microfluidic apparatus (i.e., pixel-based heating).

Besides, some applications require specific thermal management, such as thermal cycling, so it is desirable to measure or sense the temperatures of the pixels of the microfluidic apparatus for precisely controlling the specific temperatures of the pixels. However, the macroscale thermal sensor may not suffice for this purpose, let alone the conventional heater.

Therefore, the conventional configurations may not adequately address issues associated with the heating, and moreover the thermal sensing, of droplets in the EWOD-based microfluidic apparatus.

### SUMMARY OF INVENTION

According to the embodiments of the present disclosure, there is provided a heating device to independently and/or effectively heat the micro objects manipulated by a micro apparatus/system, for example the droplets of fluids in an EWOD (or AM-EWOD) device or other microfluidic device within a general microfluidic apparatus.

In an embodiment of the present disclosure, the heating device comprises a plurality of micro heaters which are arranged in an array of rows and columns, wherein each of the micro heaters comprises a heating element, a first conductive line and a second conductive line, the first conductive line is connected to a first end of the heating element, and the second conductive line is connected to a second end of heating element.

In an embodiment of the present disclosure, each of the micro heaters further comprises a substrate, and each of the heating elements, the first conductive line and the second conductive line is disposed on or above the substrate.

In an embodiment of the present disclosure, wherein each of the micro heaters further comprises an additional layer disposed on the substrate, and the heating element is disposed on the additional layer to be above the substrate.

In an embodiment of the present disclosure, wherein the heating element is a resistive heating element.

In an embodiment of the present disclosure, wherein the heating element is a patterned heating element.

In an embodiment of the present disclosure, wherein the heating element is in a snakelike or spiral pattern.

In an embodiment of the present disclosure, wherein the substrates of the micro heaters are integrally formed.

In an embodiment of the present disclosure, the microfluidic apparatus comprises: an electrowetting on dielectric (EWOD) device, configured to receive one or more droplets, the EWOD device comprising a plurality of electrode elements arranged in an array of rows and columns; and a heating device, comprising a plurality of micro heaters arranged in an array of rows and columns, wherein each of the micro heaters comprises a heating element, a first conductive line and a second conductive line, the first conductive line is connected to a first end of the heating element, and the second conductive line is connected to a second end of heating element; wherein the micro heaters of the heating device are disposed in relative to the electrode elements of the EWOD device, respectively.

In an embodiment of the present disclosure, wherein the micro heaters of the heating device are disposed below or above the electrode elements of the EWOD device, respectively.

In an embodiment of the present disclosure, wherein the micro heaters of the heating device are disposed beside the electrode elements of the EWOD device, respectively.

In an embodiment of the present disclosure, the microfluidic apparatus further comprises a plurality of thermal sensors, which are disposed above or below the electrode elements of the EWOD device, respectively.

In an embodiment of the present disclosure, the microfluidic apparatus further comprises a plurality of thermal sensors, which are disposed above or below the micro heaters of the heating device, respectively.

In an embodiment of the present disclosure, the microfluidic apparatus further comprises a plurality of thermal sensors, which are disposed beside the micro heaters of the heating device or the electrode elements of the EWOD device, respectively.

In an embodiment of the present disclosure, the EWOD device comprises a first substrate and a second substrate disposed opposite to the first substrate, the electrode elements of the EWOD device are disposed on the first substrate, and the micro heaters of the heating device are disposed on the second substrate.

In an embodiment of the present disclosure, the microfluidic apparatus further comprises a main substrate, wherein the electrode elements of the EWOD device and the micro heaters of the heating device are disposed on the main substrate.

In an embodiment of the present disclosure, the micro heaters of the heating device define a plurality of temperature zones to heat the droplet received in the EWOD device with different temperatures.

In an embodiment of the present disclosure, each of the temperature zones comprises a same number of the micro heaters.

In an embodiment of the present disclosure, each of the temperature zones comprises a different number of the micro heaters.

In an embodiment of the present disclosure, the temperature zones are arranged in concentric rings.

Based on the embodiments of the present disclosure, the micro heaters of the heating device correspond to the respective electrode elements of the EWOD device, so the micro heater may just heat one of the electrode elements to prevent thermal effect of the object on the other electrode elements. Besides, the heating device may be easily assembled or integrated with the EWOD device. On other hand, the thermal sensors associated with the micro heaters of the heating device may sense the temperature of one of the electrode elements heated by the heating device, so as to provide feedback to the heating device; thus, the micro heaters of the heating device may provide more precise heating for the electrode elements. Moreover, the configurations for the micro heater, the electrode element and the thermal sensor may be modified for different requirements of heating, driving or sensing capacity.

Furthermore, the temperatures of the micro heaters in the temperature zones are substantially kept during the operation of the microfluidic apparatus, instead of being frequently or intentionally changed, so it is possible to save the time and/power to heat the electrode elements of the EWOD device.

Further features of the present disclosure will become apparent from the following description of exemplary embodiments (with reference to the attached drawings).

### BRIEF DESCRIPTION OF DRAWINGS

FIGS. 1 and 2 are top views illustrating the configuration of a heating device in accordance with a first embodiment of the present disclosure;

FIG. 3 is a side view illustrating the configuration of a micro heater in the heating device of FIG. 1;

FIG. 4 is a top view illustrating the configuration of the micro heater in the heating device of FIG. 1;

FIG. 5 is a side view illustrating the configuration of a microfluidic apparatus in accordance with a second embodiment of the present disclosure;

FIG. 6 is a side view illustrating the configuration of the micro heater and the electrode elements in the microfluidic apparatus of FIG. 5;

FIG. 7 is a side view illustrating the configuration of a microfluidic apparatus in accordance with a third embodiment of the present disclosure;

FIG. 8 is a schematic view illustrating the circuit diagram of the microfluidic apparatus of FIG. 5 or FIG. 7;

FIG. 9 is a side view illustrating the configuration of a microfluidic apparatus in accordance with a fourth embodiment of the present disclosure;

FIG. 10 is a top view illustrating the configuration of the thermal sensors in the microfluidic apparatus of FIG. 9;

FIG. 11 is a top view illustrating the alternative configuration of the microfluidic apparatus of FIG. 9;

FIG. 12A is a schematic view illustrating the temperature of the droplet in each of the pixels in the microfluidic apparatus of FIG. 9;

FIGS. 12B and 12C are schematic views illustrating the temperature zones defined by the pixels in the microfluidic apparatus;

FIGS. 13A to 13E are side views illustrating more alternative configurations of the microfluidic apparatus of FIG. 9;

FIG. 14A is a schematic view illustrating the circuit diagram of the microfluidic apparatus of one of FIG. 9 and FIGS. 13A to 13E;

FIGS. 14B to 14D are schematic views illustrating the circuit diagram of the thermal sensor in the microfluidic apparatus of one of FIG. 9 and FIGS. 13A to 13E;

FIGS. 14E to 14H are schematic views illustrating the alternative circuit diagrams of the microfluidic apparatus of one of FIG. 9 and FIGS. 13A to 13E; and

FIGS. 15A to 15E are schematic views illustrating more alternative circuit diagrams of the microfluidic apparatus of one of FIG. 9 and FIGS. 13A to 13E.

### DETAILED DESCRIPTION

In the following description, numerous specific details are set forth to provide a thorough understanding of embodiments of the present disclosure. It will be apparent to person having ordinary skill in the art that the embodiments of the present disclosure may be practiced without those specific details. In other instances, well-known features, such as thin-film transistor (TFT), electrowetting-on-dielectric (EWOD), circuit design layouts, may be not described in detail so as to not unnecessarily obscure the embodiments of the present disclosure. Moreover, multiple features are described in the embodiments, but no limitation is made to an invention that requires all such technical features, and such technical features may be combined or replaced as appropriate. Furthermore, in the attached drawings, the same reference numerals are given to the same or similar components, and redundant description thereof may be omitted. It is to be appreciated that the components shown in the attached drawings may not necessarily be drawn to scale.

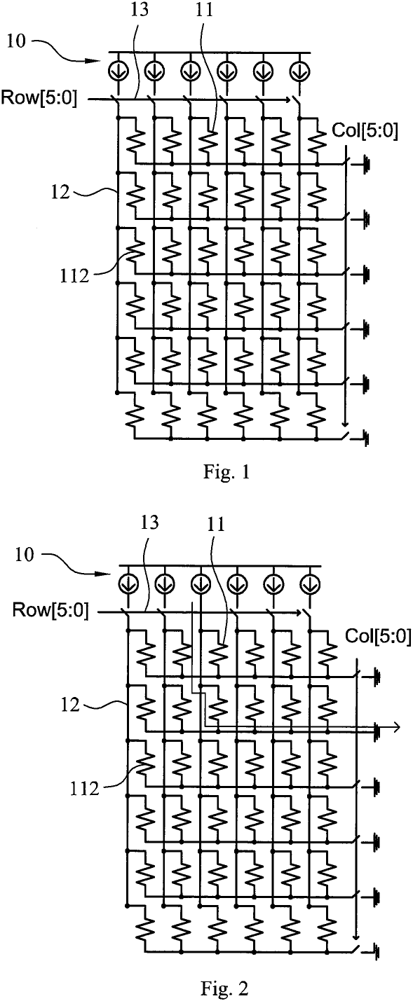

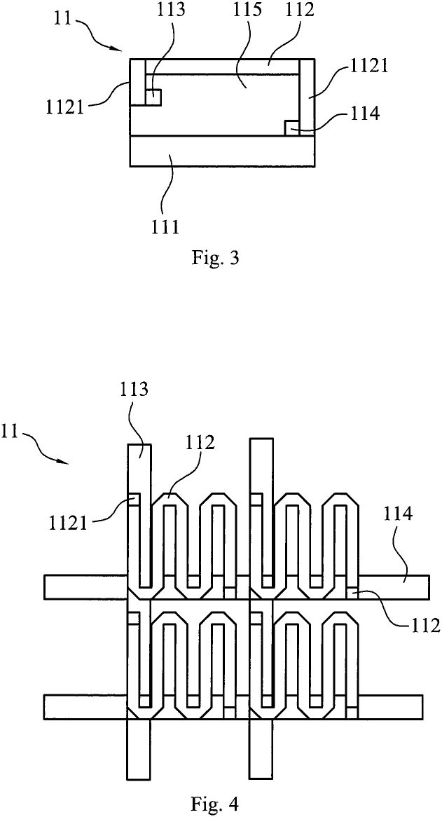

Please refer to FIGS. 1 and 2, according to a first embodiment of the present disclosure, a heating device 10 is disclosed that can/may be used in a microfluidic apparatus (its technical features will be described later) for example. The heating device 10 comprises a plurality of micro heaters 11 which are arranged in an array of rows and columns to form a matrix array. The numbers of rows and columns in the array of the micro heaters 11 are not limited and may correspond to the numbers of rows and columns in the array of the electrode elements in the microfluidic apparatus.

Each of the columns (e.g., five columns) may include a column addressing line (e.g., metal line) 12 that provides a control signal to a corresponding column of the micro heaters 11, and each of the rows (e.g., five rows) may include a row addressing line 13 that provides a control signal to a corresponding row of the micro heaters 11. For example, when one of the column addressing lines 12 is active (Col [i] = high) and one of the row addressing lines 13 is active (Row [i] = high), the corresponding switches are turn on to allow electrical current flowing through the micro heater 11 to generate heat. Normally, only one of the column addressing lines 12 and one of the row addressing lines 13 are active to avoid the unintended actuation of the micro heaters 11. However, two or more of the column addressing lines 12 or the row addressing lines 13 may be active to actuate two or more of the micro heaters 11.

Each of the micro heaters 11 may comprise a heating element 112, such as a resistive heating element (e.g. poly resistor) or other kinds of heating elements that may generate heat as a result of electrical energy flowing therethrough. The heating element 112 may be made by metallic, metal-ceramic or ceramic material. Moreover, the length/width of the micro heater 11 may be 100 µm, and the interval between two adjacent micro heaters 11 may be 5 µm; the size/dimension may be varied according to the practical application, such as the diameter of the micro object (e.g., droplet of fluid) to be heated by the micro heater 11.

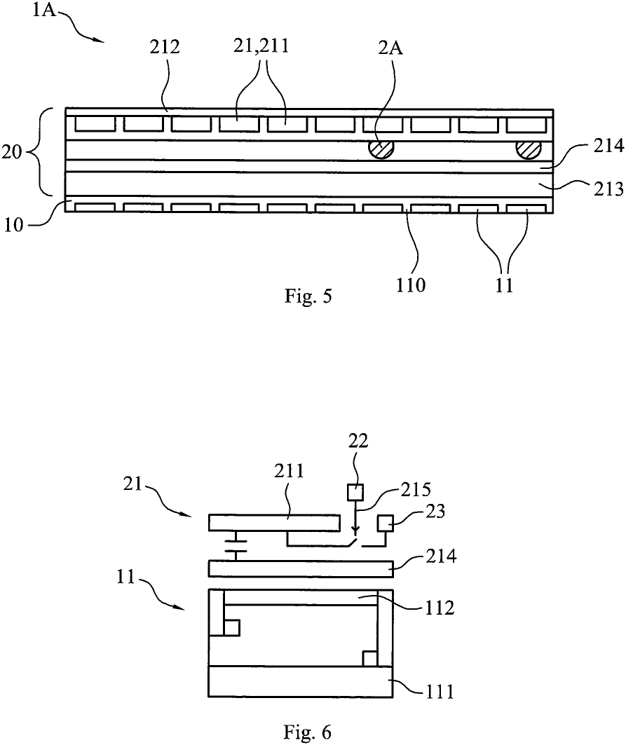

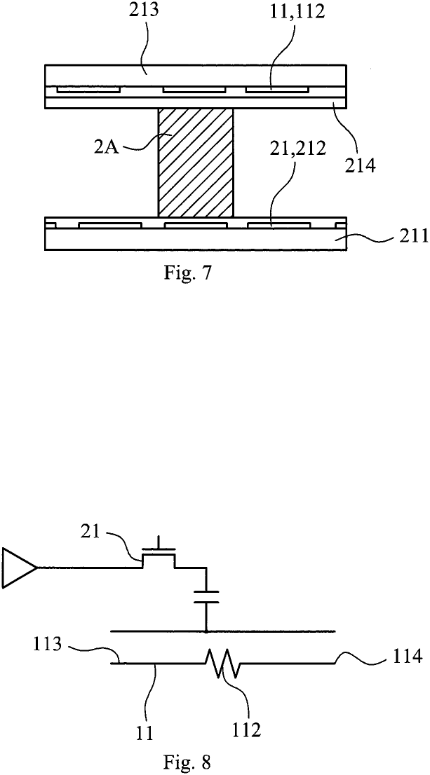

Please refer to FIGS. 3 and 4, each of the micro heaters 11 may be formed/designed as or in a thin film structure similar to a thin-film-transistor (TFT). Specifically, each of the micro heaters 11 may comprise a substrate 111, a heating element 112, a first conductive line (i.e., first conductive/metal layer) 113 and a second conductive line (i.e., second conductive/metal layer) 114. The heating element 112 is disposed above the substrate 111 as the micro heater 11 further comprises one or more than one additional layers 115 between the heating element 112 and the substrate 111. That is said, the additional layer 115 is disposed on the substrate 111, and the heating element 112 is then disposed on the additional layer 115 to be above the substrate 111; the additional layer 115 may be made by dielectric materials.

The substrate 111 and the heating element 112 may be referred as a bottom layer and a top layer, respectively. The heating element 112 as the top layer may be adjacent to the object to be heated, so the heat generated is more effectively transferred to the object. In other embodiment (not shown), the heating element 112 may be disposed on the substrate 111, so as to reduce the thickness of the micro heater 11 or facilitate the fabrication of the micro heater 11. The heating element 112 may be a patterned heating element, instead of in a simple shape (e.g., circle, triangle, and rectangle); that is said, the heating element 112 may be in a snakelike or spiral pattern, so as to improve the temperature distribution across the heating element 112.

The first conductive line 113 and the second conductive line 114 are disposed on or above the substrate 111; specifically, the first conductive line 113 is disposed on the additional layer 115 to be above the substrate 111 and the second conductive line 114 is disposed on the substrate 111. The first conductive line 113 and the second conductive line 114 may be disposed between the heating element 112 and the substrate 111, or alternatively, one of the first conductive line 113 and the second conductive line 114 may be disposed on the same layer with the heating element 112. The first conductive line 113 is connected to a first end of the heating element 112 by a contact 1121, while the second conductive line 114 is connected to a second end of the heating element 112 by a contact 1121; the contact 1121 may be electrical via or any suitable conductive structure.

The first conductive line 113 may be further connected to the corresponding column addressing line 12 and the second conductive line 114 may be further connected to the corresponding row addressing line 13. Thus, the heating element 112 may be directly controlled or actuated by the column addressing line 12 and the row addressing line 13, without using an active control component. In other embodiment (not shown), if a controller of switch for the first and second conductive lines 113 and 114 is needed, the controller may be formed within the micro heater 11 or outside the micro heater 11. The first conductive line 113 and the column addressing line 12 may be integrally formed as the same conductive line, and the second conductive line 114 and the row addressing line 13 may be integrally formed as the same conductive line.

It is noted that the substrates 111 of all the micro heaters 11 may be integrally formed as a single and large substrate (main substrate). Thus, the heating elements 111, the first conductive lines 113, the second conductive lines 114 of all the micro heaters 11, as well as the column addressing lines 12 and the row addressing lines 13, are disposed on or above the main substrate to form the heating device 10.

Via the above technical contents, the heating device 10 may independently and individually actuate the micro heaters 11 to heat the objects nearby. While the micro heaters 11 in the embodiment generate heat by electrical resistance, the micro heaters 11 may generate heat by other manners. For example, other heating manner for the micro heaters 11 may involve the inductive heating, microwave heating or optical heating (thermal radiation).

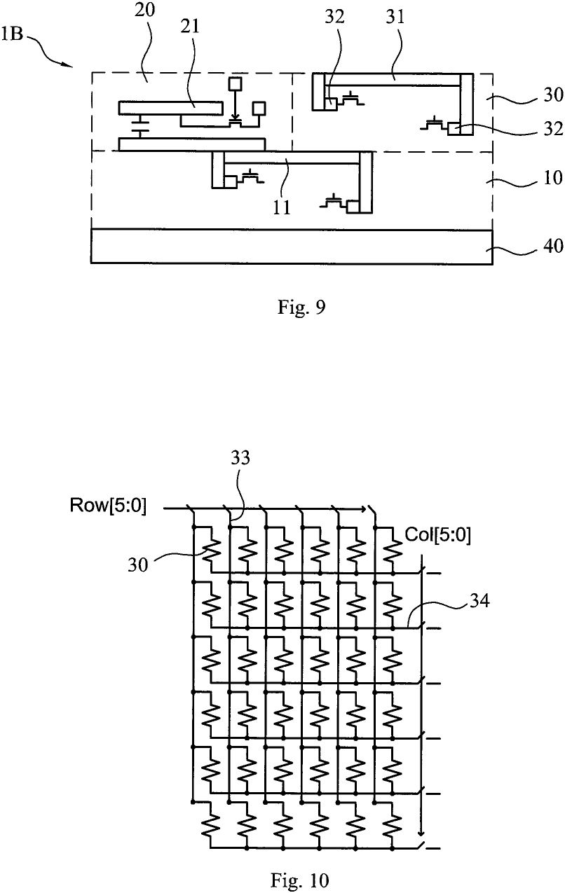

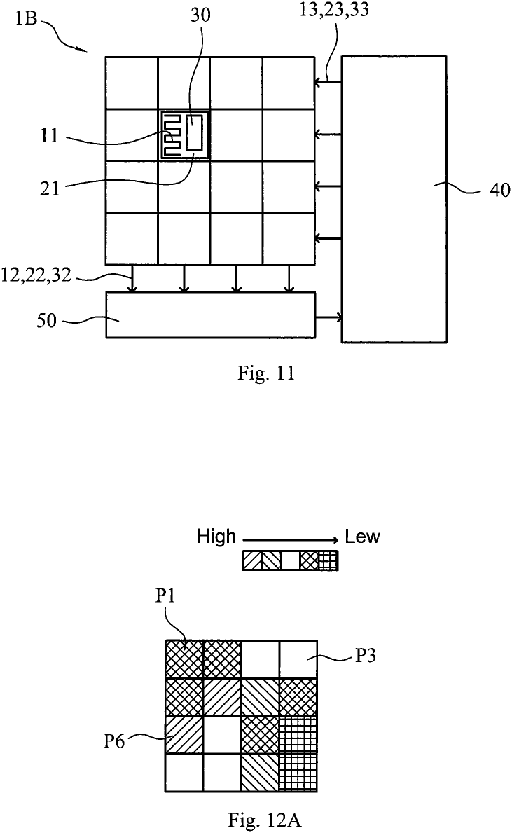

Please refer to FIGS. 5 and 6, according to a second embodiment of the present disclosure, a microfluidic apparatus 1A is disclosed. The microfluidic apparatus 1A may comprise an electrowetting-on-dielectric (EWOD) device 20 for receiving one or more droplets 2A of fluid (i.e., micro object), and a heating device 10, which may be the same or similar to the heating device 10 as described above, for heating the droplets 2A. The EWOD device 20 may be an active matrix EWOD (AM-EWOD) device that comprises a plurality of electrode elements (driver cells or pixels) 21 arranged in an array of rows and columns to form a matrix array. The droplets 2A can be moved from one of electrode elements 21 to the adjacent ones along the same row or column.

More specifically, each of the electrode elements 21 in the EWOD device 20 may comprise an electrode 211, a first substrate 212, a second substrate 213 disposed opposite to the first substrate 22 and a common electrode 214, the electrode 211 is disposed on the first substrate 212, and the common electrode 214 is disposed on the second substrate 213. The droplet 2A is received in the space defined between the first substrate 212 and second substrate 213. Each of the columns in the EWOD device 20 may include a column addressing line 22 electrically connected to the electrode elements 21 along the corresponding column, so as to provide a control signal to the corresponding column of the electrode elements 21; each of the rows in the EWOD device 20 may include a row addressing line 23 electrically connected to the electrode elements 21 along the corresponding row, so as to provide a control signal to the corresponding row of the electrode elements 21.

Each of the electrode elements 21 may further comprise a thin-film transistor (TFT) 215, or other suitable transistor or switch, coupled to the electrode 211. The gate of the TFT 215 may be connected to the column addressing line 22, the drain of the TFT 215 may be connected to the row addressing line 23 and the source of the TFT 215 may be connected to the electrode 211. A voltage can be applied between the electrode 211 and the common electrode 214 via the TFT 215 to enable the movement of droplet 2A.

The micro heaters 11 of the heating device 10 are disposed in relative to the electrode elements 21 of the EWOD device 20, respectively. For example, the micro heaters 11 are disposed below the electrode elements 21, respectively, and are arranged in the array of rows and columns similar or identical to the array of the electrode elements 21. Thus, each of the electrode elements 21 may have one of the micro heaters 11 underneath. The micro heaters 11 are directly formed on, or in contact with, a lower side of the second substrates 213 of the electrode elements 21, which is opposite to an upper side where the common electrode 214 is formed. The micro heaters 11 may also slightly separate from the second substrates 213 of the electrode elements 21, with layer or structure therebetween.

Since the heating element 112 is disposed adjacent to the corresponding electrode element 21, rather than being remote from the electrode element 21, the heat generated by the heating element 112 may be more effectively/quickly transferred to the droplet 2A on or above the electrode element 21.

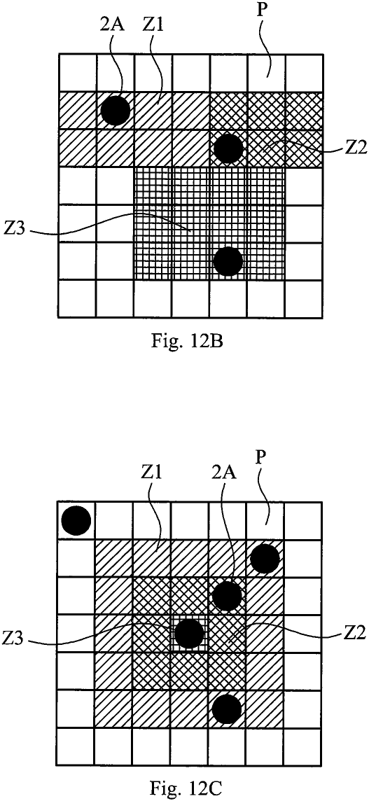

Please refer to FIG. 7, according to a third embodiment of the present disclosure, the micro heater 11 (heating element 112) may be disposed/formed on the second substrate 213 of the electrode element 21, one the same side where the common electrode 214 is disposed. Thus, the micro heater 11 may be closer to the droplet 2A to provide rapid heating. The micro heater 11 (heating element 112) may be electrically isolated from the common electrode 214 by a dielectric layer therebetween.

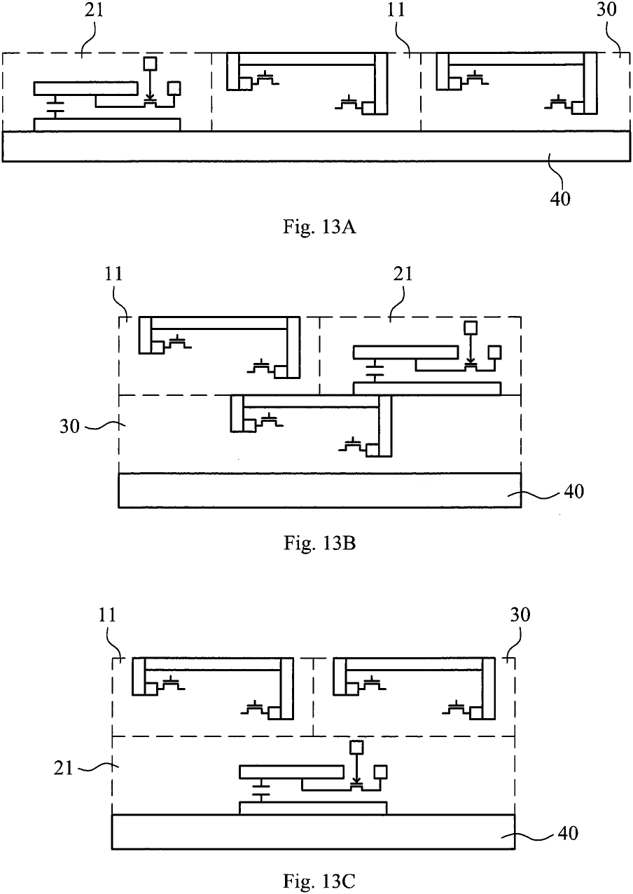

Please refer to FIG. 8, a circuit diagram is depicted to show the micro heater 11 and the electrode element 21 in one pixel as described above.

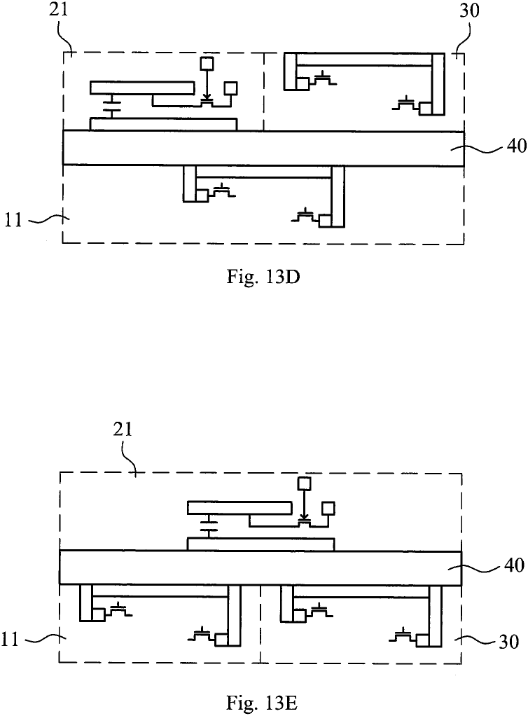

Please refer to FIGS. 9 to 11, according to a fourth embodiment of the present disclosure, a microfluidic apparatus 1B is disclosed. The microfluidic apparatus 1B is similar to the microfluidic apparatus 1A as described above and further comprises a plurality of thermal sensors 30 for sensing the temperature of the droplets 2A in the electrode elements 21 of the EWOD device 20. The thermal sensors 30 are disposed in relative to the electrode elements 21 of the EWOD device 20, respectively. For example, the thermal sensor 30 are disposed beside the electrode elements 21, respectively, and the thermal sensor 30 and the electrode element 21 both may be disposed above or on the micro heater 11 in the same pixel of the array. Thus, each of the electrode elements 21 may have one of the thermal sensors 30 beside.

The thermal sensor 30 may be structurally similar to the micro heater 11, as the heating element 112 of the micro heater 11 may have a material property of temperature coefficient of resistance (TCR) that relates electrical resistance to temperature. More specifically, the thermal sensor 30 may include a resistive sensing element (e.g. N+ poly resistor) 31 and two readout pins (i.e., conductive lines) 32 connected to the two ends of the sensing element 31, respectively. The resistance of the sensing element 31 is measured via the two readout pins 32 to estimate the temperature of the droplet 2A nearby, so that how the droplet 2A is heated by the micro heater 11 may be known.

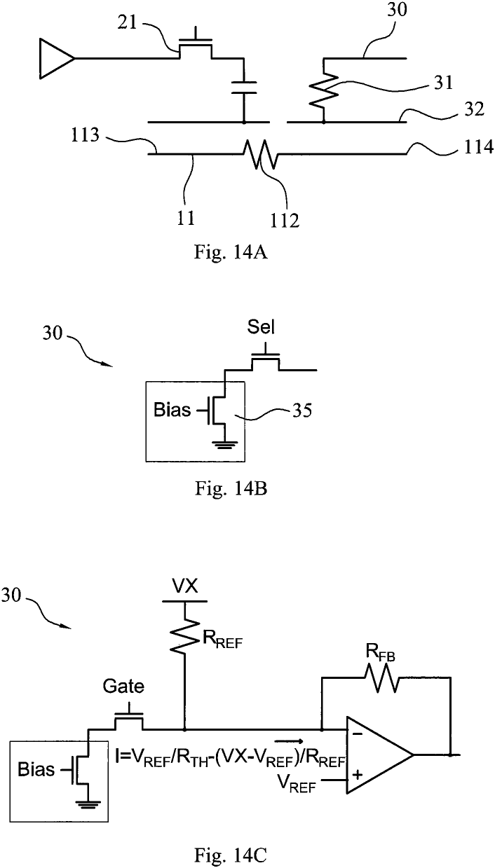

Furthermore, as illustrated in FIG. 10, the thermal sensors 30 are arranged in the array of rows and columns similar or identical to the array of the micro heaters 11 or electrode elements 21. Each of the columns includes a column addressing line 33 that is connected to a corresponding column of the thermal sensors 30, and each of the rows includes a row addressing line 34 that is connected to a corresponding row of the thermal sensors 30. For example, when the third column addressing lines is active and the third row addressing lines is active, the effect signal of the corresponding thermal sensor 30 may be read out through its readout pins 32.

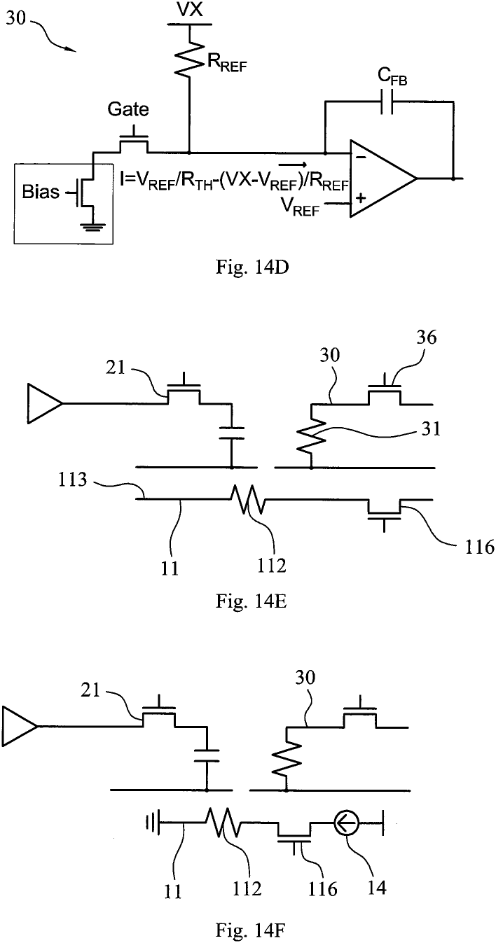

As illustrated in FIG. 11, The microfluidic apparatus 1B may additionally comprise a controller 40 and a readout circuit 50, the controller 40 is connected to each of the electrode elements 21 through the column addressing line 22 and row addressing line 23 in the EWOD device 20, and the controller 40 is also connected to each of the micro heaters 11 through the column addressing line 12 and row addressing line 13 in the heating device 10, so as to control the actuation or operation of the electrode elements 21 and the micro heaters 11. The readout circuit 50 is connected to each of the thermal sensors 30 through the column addressing line 32 and row addressing line 34 for reading the signals from the thermal sensors 30. The controlled 40 is also connected to the readout circuit 50 to read the signal from the readout circuit 50, so as to obtain the temperature of the droplet 2A in the pixel of array.

Therefore, the controller 40 in a “closed loop feedback” mode can control the micro heater 11 (turn on/off the heater 11, or adjust the current to the heater 11) based on the detected temperature of the droplet 2A, so that the temperature of the droplet 2A may be precisely controlled to be desired one. It is noted that the readout circuit 50 may included or embedded in the controller 40.

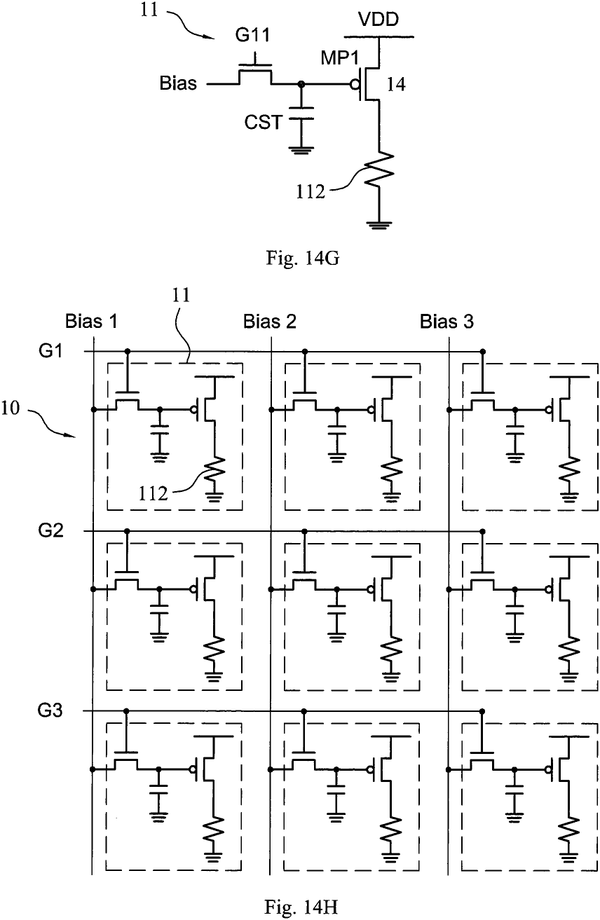

As illustrated in FIG. 12A, by virtue of the heating device 10 with the micro heaters 11 and the thermal sensors 30, the temperature of the droplet in each of the pixels may be independently and precisely set; namely, the user can set the temperature of the droplet in the first pixel P1 to be higher than the temperature of the droplet in the third pixel P3, which is lower than the temperature of the droplet in the sixth pixel P6, for example.

More specifically, as shown in FIG. 12B, the pixels P (micro heaters 11) may be set to have different temperatures to define a plurality of temperature zones Z1, Z2 and Z3; the temperature zones Z1, Z2 and Z3 may be defined by just one pixel P or by several pixels P, and the temperature zones Z1, Z2 and Z3 may comprise the same or different dimensions (numbers of the micro heaters 11). The temperatures in the temperature zones Z1, Z2 and Z3 would be substantially kept during the operation of the microfluidic apparatus 1B, instead of being changed; for example, the temperature zones Z1, Z2 and Z3 are maintained at 30° C., 45° C. and 65° C., respectively. The droplet 2A moves to and stays in one of the temperature zones Z1, Z2 and Z3 to have desired temperature, or the droplet 2A may move from the temperature zone Z1 to the temperature zones Z2 and Z3 to be gradually heated. As such, when the droplet 2A leaves for the temperature zone Z2 from the temperature zone Z1, the other droplet 2A can move onto the unoccupied pixel P in the temperature zone Z1.

Please also refer to FIG. 12C, the temperature zones Z1, Z2 and Z3 may be generally arranged in one or more concentric rings, namely, the temperature zone Z1 surrounds the temperature zone Z2 which surrounds the temperature zone Z3. The droplet 2A can move from the periphery temperature zone Z1 to the center temperature zone Z3 to undergo gradual heating, and can be also manipulated/ processed in the center temperature zone Z3.

Therefore, without frequently or intentionally changing the temperatures of the pixels (micro heaters) in the temperature zones during the operation of the microfluidic apparatus, it is possible to save the time and/power to heat the droplets (the electrode elements of the EWOD device).

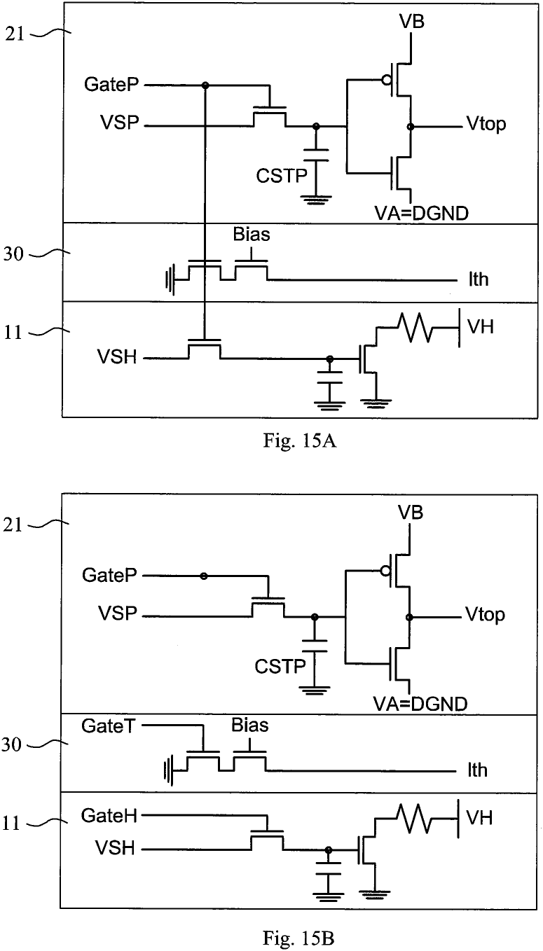

Please refer to FIGS. 13A to 13F, except for the above configuration illustrated in FIG. 9 that the electrode element 21 of the EWOD device 20 and the thermal sensor 30 are formed/disposed on the micro heater 11 of the heating device 10 in one pixel, the micro heater 11, the electrode element 21 and the thermal sensor 30 in one pixel of the microfluidic apparatus 1B may be arranged in other configurations according to the driving effect for those components. By way of illustration, as illustrated in FIG. 13A, the micro heater 11 may be formed/disposed between the electrode element 21 and the thermal sensor 30 on a main substrate 40, so the micro heater 11, the electrode element 21 and the thermal sensor 30 may have equal driving effects; as illustrated in FIG. 13B, the electrode element 21 and the micro heater 11 may be formed/disposed on the thermal sensor 30, so the thermal sensor 30 on the main substrate 40 may have better driving effect; as illustrated in FIG. 13C, the thermal sensor 30 and the micro heater 11 may be formed/disposed on the electrode element 21, so the electrode element 21 on the main substrate 40 may have better driving effect.

As illustrated in FIGS. 13D and 13E, by using certain advanced techniques (e.g., precision hole process), one or two of the micro heater 11, the electrode element 21 and the thermal sensor 30 may be formed/disposed below the main substrate 40, so the micro heater 11, the electrode element 21 and the thermal sensor 30 may have equal driving effects.

Moreover, the ratio of the electrode element 21 to the micro heater 11 to the thermal sensor 30 in one pixel unit is n:m:k, wherein the numerals n, m and k may be identical or different from one another. For instance, the pixel unit has one electrode element 21 (n=1), two micro heaters 11 (m=2) and one thermal sensor 30 (k=1), or the pixel unit has two electrode element 21 (n=2), one micro heater 11 (m=1) and one thermal sensor 30 (k=l).

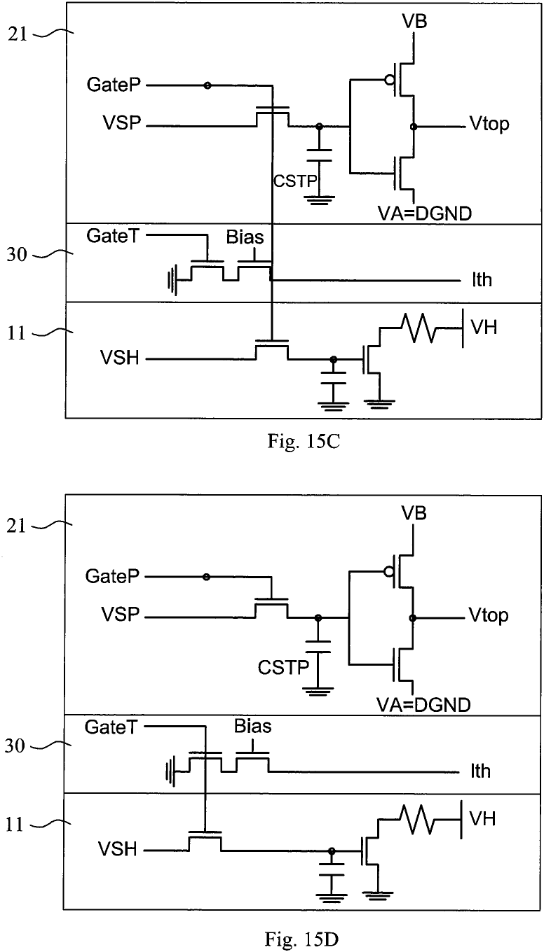

Please refer to FIG. 14A, a circuit diagram is depicted to show the micro heater 11, the electrode element 21 and the thermal sensor 30 in one pixel of the microfluidic apparatus 1B as described in the above embodiments.

Alternatively, the thermal sensor 30 may include a diode, transistor or other suitable components able to sense temperature. For example, as shown in FIG. 14B, when the transistor 35 of thermal sensor 30 is operated under certain biasing, the transistor 35 may have temperature dependence with respect to its resistance or current. The thermal sensor 30 may be formed/designed as or in a TFT structure as well.

FIG. 14C depicts a more specific circuit diagram of the thermal sensor 30 with the transistor 35. The R_{REF} refers to the reference resistor, and the current flowing through the feedback resistor R_{FB} is: V_{REF}/R_{TH}-(VX-V_{REF})/R_{REF}. When the reference resistor R_{REF} is too large (infinite), i.e., amounting to an open state, the current flowing to the operational amplifier may be too large, thereby resulting in too much voltage developed across R_{FB} to render the dynamic range small; the thermal sensor 30 might be still functional in this situation although. If the R_{REF} is limited, adjusting VX or R_{REF} may make the current flowing through R_{FB} sufficiently small, such that the direct portion of the current (signal) of the thermal sensor 30 may be removed to improve the dynamic range. Namely, the effect signal generated by the thermal sensor 30 as temperature varying may be obvious to be detected.

FIG. 14D depicts another more specific circuit diagram of the thermal sensor 30 with the transistor 35, which utilizes an integrating amplifier by a feedback capacitor C_{FB}, and thus the effect signal generated by the thermal sensor 30 as temperature varying may also be obvious to be detected.

As illustrated in FIG. 14E, the circuit for the micro heater 11 and the thermal sensor 30 in each pixel may be connected to respective switches (e.g., TFTs) 116 and 36. The switch 116 of the micro heater 11 (heat selection) determines whether the micro heater 11 is active to generate heat, and the switch 36 of the thermal sensor 30 (sensor selection) determines whether the thermal sensor 30 is active to sense the temperature of the droplet in the electrode element.

As illustrated in FIGS. 14F and 14G, the micro heater 11 may be connected to a current source 14, instead of a voltage source, to provide electric current to the micro heater 11 (heating element 112). Specifically, as shown in FIG. 14G, if the node Bias and the gate G11 are provided with suitable voltage, the PMOS transistor MP1 will be turn on to allow the electric current from the current source 14 to the micro heater 11.

As illustrated in FIG. 14H, the micro heaters 11 with the current source 14 may be arranged in an array of rows and columns (e.g., a 3x3 array) and may be operated as described above. Specifically, if the first row addressing line (i.e., the gate line Gl) is at high state and the second and third row addressing line (i.e., the gate lines G2 and G3) are at low state, the micro heaters 11 in the first row can be heated by the voltage provided to the column addressing lines (i.e., the lines Bias1, Bias2 and Bias3). If it is the case that G1=low, G2=high and G3=low, the micro heaters 11 in the second row can be heated by the voltage provided to the column addressing lines (i.e., the lines Bias1, Bias2 and Bias3).

Alternatively, an NMOS transistor may be used to control the current source 14 as well. The “2T1C (i.e., 2 Transistor with 1 Capacitor),” “3T1C” or even “7T1C” type circuit may be used to control the current source 14 as well.

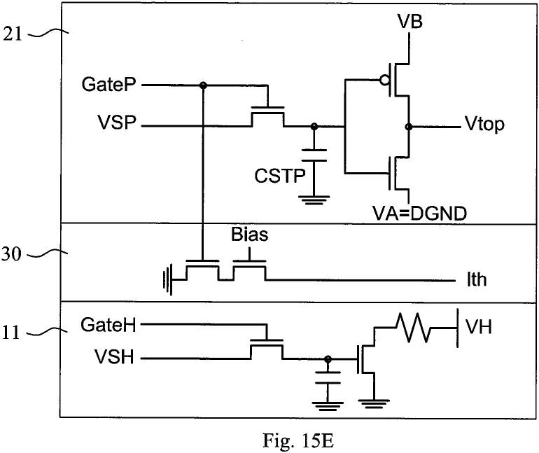

It is noted that the operation speeds of the micro heater 11, the electrode element 21 and the thermal sensor 30 may be different. If a control signal (gate signal) is provided to the micro heater 11, the electrode element 21 and the thermal sensor 30 simultaneously (i.e., synchronous controlling) as referred to FIG. 15A, the droplet may be moved onto the electrode element 21 before the micro heater 11 heats the electrode element 21. To address this, as referred to FIG. 15B, three signals may be provided to the gate H of the micro heater 11, the gate P of the electrode element 21 and the gate T of the thermal sensor 30 respectively to control the micro heater 11, the electrode element 21 and the thermal sensor 30 asynchronously; thus, the droplet may be moved onto the electrode element 21 after the micro heater 11 has heated the electrode element 21, and the thermal sensor 30 is ready.

Alternatively, as referred to FIG. 15C, a signal may be provided to the gate H of the micro heater 11 and the gate P of the electrode element 21 synchronously, while another signal may be provided to the gate T of the thermal sensor 30; as referred to FIG. 15D, a signal may be provided to the gate H of the micro heater 11 and the gate T of the thermal sensor 30 synchronously; as referred to FIG. 15E, a signal may be provided to the gate P of the electrode element 21 and the gate T of the thermal sensor 30 synchronously.

It should be understood by those skilled in the art that various modifications, combinations, sub-combinations and alterations may occur depending on design requirements and other factors insofar as they are within the scope of the accompanying claims or the equivalents thereof.

1. A heating device, comprising a plurality of micro heaters which are arranged in an array of rows and columns, wherein each of the micro heaters comprises a heating element, a first conductive line and a second conductive line, the first conductive line is connected to a first end of the heating element, and the second conductive line is connected to a second end of heating element.

2. The heating device according to claim 1, wherein each of the micro heaters further comprises a substrate, and each of the heating element, the first conductive line and the second conductive line is disposed on or above the substrate.

3. The heating device according to claim 2, wherein each of the micro heaters further comprises an additional layer disposed on the substrate, and the heating element is disposed on the additional layer to be above the substrate.

4. The heating device according to claim 1, wherein the heating element is a resistive heating element.

5. The heating device according to claim 1, wherein the heating element is a patterned heating element.

6. The heating device according to claim 5, wherein the heating element is in a snakelike or spiral pattern.

7. The heating device according to claim 1, wherein the substrates of the micro heaters are integrally formed.

8. An microfluidic apparatus comprising:
an electrowetting on dielectric (EWOD) device, configured to receive one or more droplets, the EWOD device comprising a plurality of electrode elements arranged in an array of rows and columns; and
a heating device, comprising a plurality of micro heaters arranged in an array of rows and columns, wherein each of the micro heaters comprises a heating element, a first conductive line and a second conductive line, the first conductive line is connected to a first end of the heating element, and the second conductive line is connected to a second end of heating element;
wherein the micro heaters of the heating device are disposed in relative to the electrode elements of the EWOD device, respectively.

9. The microfluidic apparatus according to claim 8, wherein the micro heaters of the heating device are disposed below or above the electrode elements of the EWOD device, respectively.

10. The microfluidic apparatus according to claim 8, wherein the micro heaters of the heating device are disposed beside the electrode elements of the EWOD device, respectively.

11. The microfluidic apparatus according to claim 8, further comprising a plurality of thermal sensors, which are disposed above or below the electrode elements of the EWOD device, respectively.

12. The microfluidic apparatus according to claim 8, further comprising a plurality of thermal sensors, which are disposed above or below the micro heaters of the heating device, respectively.

13. The microfluidic apparatus according to claim 8, further comprising a plurality of thermal sensors, which are disposed beside the micro heaters of the heating device or the electrode elements of the EWOD device, respectively.

14. The microfluidic apparatus according to claim 8, wherein each of the electrode elements of the EWOD device comprises an electrode, a first substrate and a second substrate disposed opposite to the first substrate, the electrode is disposed on the first substrate, and the micro heater is disposed on the second substrate.

15. The microfluidic apparatus according to claim 8, further comprising a main substrate, wherein the electrode elements of the EWOD device and the micro heaters of the heating device are disposed on the main substrate.

16. The microfluidic apparatus according to claim 8, wherein the micro heaters of the heating device define a plurality of temperature zones to heat the droplet received in the EWOD device with different temperatures.

17. The microfluidic apparatus according to claim 16, wherein each of the temperature zones comprises a same number of the micro heaters.

18. The microfluidic apparatus according to claim 16, wherein each of the temperature zones comprises a different number of the micro heaters.

19. The microfluidic apparatus according to claim 16, wherein the temperature zones are arranged in concentric rings.
